(19) United States
(12) Patent Application Publication
(10) Pub. No.: US 2002/0144784 A1
(43) Pub. Date: Oct. 10, 2002

(54) Wafer processing apparatus having a chamber with an upper wall having gas supply openings formed therein which promote more even processing of a wafer

(76) Inventors: Don E. Curry, Meridian, ID (US); Jeffrey E. Fletcher, Boise, ID (US)

Correspondence Address: APPLIED MATERIALS, INC., 2881 SCOTT BLVD. M/S 2061, SANTA CLARA, CA, 95050, US

(21) Appl. No.: 09/828,067

(22) Filed: Apr. 6, 2001

(51) Int. Cl. C23F 1/00; C23C 16/00

(52) U.S. Cl. 156/345.33; 118/715

(57) ABSTRACT

The invention relates to wafer processing apparatus having a chamber with an upper wall with gas supply openings formed therein which promote more even processing of a wafer. According to one embodiment of the invention, the openings are formed so as to create a circular flow path in the chamber. Another embodiment of the invention provides for the formation of the openings to create turbulent flow. A further embodiment of the invention provides for a nonuniform distribution of the openings so as to counteract a tendency for a flow over a wafer in one area to be higher than in another area.

### BACKGROUND OF THE INVENTION

1). Field of the Invention

This invention relates to wafer processing apparatus.

2). Discussion of Related Art

FIG. 1 of the accompanying drawings illustrates apparatus 310, according to the prior art, that is used for processing a wafer 312. The wafer 312 is located on a susceptor 314. A pump 316 is operated to create a vacuum within a chamber 318. A processing gas flows through a gas supply line 320 into a manifold cavity 322. The gas then flows through openings 324 in an upper wall 326 of the chamber 318. The openings 324 in the upper wall 326 are all entirely vertical and uniformly spaced over the upper wall 326. The gas then flows radially outwardly over the wafer 312 and into a channel 328 surrounding the susceptor 314. The gas then exits through an exhaust line 330 which is connected on a left-hand side of the chamber 318.

Because the exhaust line 330 is connected to a location on a left-hand side of the chamber 318, there is a tendency for flow over the wafer 312 to be more to the left. A higher flowrate results over the left of the wafer than over the right of the wafer 312.

FIG. 2 illustrates how the wafer 312 is processed. In the example described, a layer 332 is deposited on the wafer 312. The layer 332 is thicker on the right-hand side 312 than on a left-hand side of the wafer 312 because of a higher flowrate over the left-hand side of the wafer 312.

### SUMMARY OF THE INVENTION

This invention relates to a wafer processing apparatus of the kind including a processing chamber, a susceptor, a manifold, a gas supply line, and an exhaust line. The processing chamber is defined by a lower wall, an upper wall, and sidewalls extending from the lower wall to the upper wall. A wafer supply opening is formed in one of the walls for transferring the wafer into the chamber. The upper wall has a plurality of gas supply openings, each formed into an upper surface and out of a lower surface thereof. The susceptor is located in the chamber. A wafer can be located so that an upper surface of the wafer faces the upper wall. The manifold component is located on the chamber and, together with the upper surface of the upper wall, defines a manifold cavity. The gas supply line is connected to the manifold component. The exhaust line is connected to the chamber. A gas, when flowing in the gas supply line, flows from the gas supply line into the manifold cavity and from the manifold cavity through the gas supply openings into the chamber. The wafer is exposed to the gas. The gas flows from the chamber through the exhaust line.

According to one aspect of the invention, lower ends of at least some of the openings extend at an angle other than at right angles relative to the upper surface of the wafer so that the gas, when leaving the openings flows at an angle other than at right angles relative to the upper surface. A flow pattern created by flow from the openings promotes even processing over the upper surface of the wafer.

According to another aspect of the invention the gas supply openings are nonuniformily distributed over the upper wall so that the gas, after leaving the gas supply openings, create a flow pattern that promotes even processing over the upper surface of the wafer.

### BRIEF DESCRIPTION OF THE DRAWINGS

The invention is further described by way of examples with reference to the accompanying drawings wherein:

FIG. 1 is a cross-sectional side view of a wafer processing apparatus according to the prior art;

FIG. 2 is a cross-sectional side view illustrating deposition on a wafer utilizing apparatus of FIG. 1;

FIG. 3 is a cross-sectional side view of wafer processing apparatus according to one embodiment of the invention;

FIG. 4 is a cross-sectional side view illustrating a gas supply opening in an upper wall of a chamber of the apparatus of FIG. 4;

FIG. 5 is a plan view of the upper wall;

FIG. 6 is a plan view illustrating a flow pattern of gas as the gas enters the chamber;

FIG. 7 illustrates a flow pattern over a wafer in the chamber;

FIG. 8 is a cross-sectional side view of apparatus for processing wafer, according to another embodiment of the invention;

FIG. 9 is a cross-sectional side view of an upper wall of a chamber of the apparatus of FIG. 8;

FIG. 10 is a cross-sectional side view of wafer processing apparatus according to a further embodiment of the invention; and

FIG. 11 is a plan view of an upper wall of a chamber of the apparatus of FIG. 10.

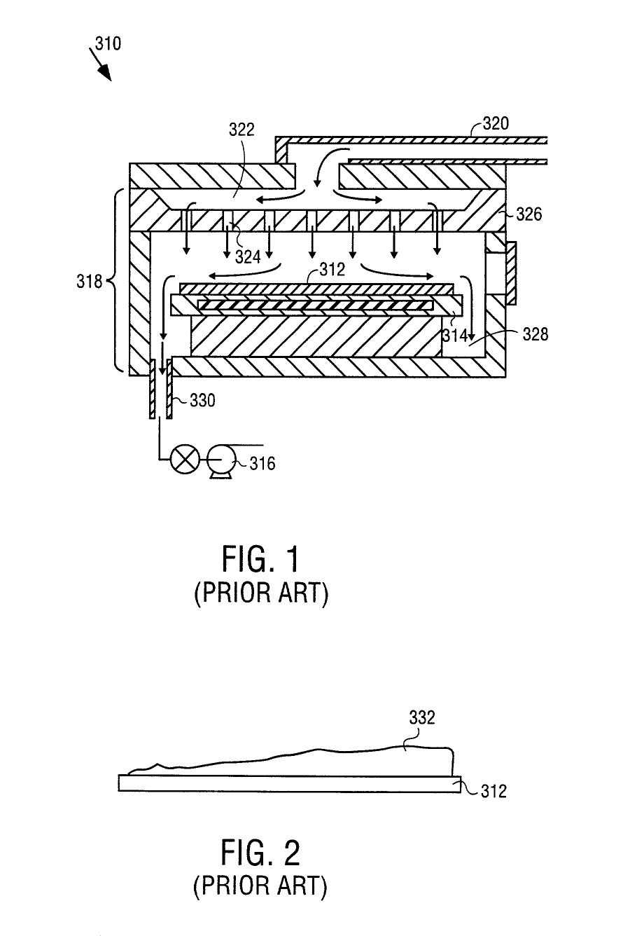

### DETAILED DESCRIPTION OF THE INVENTION

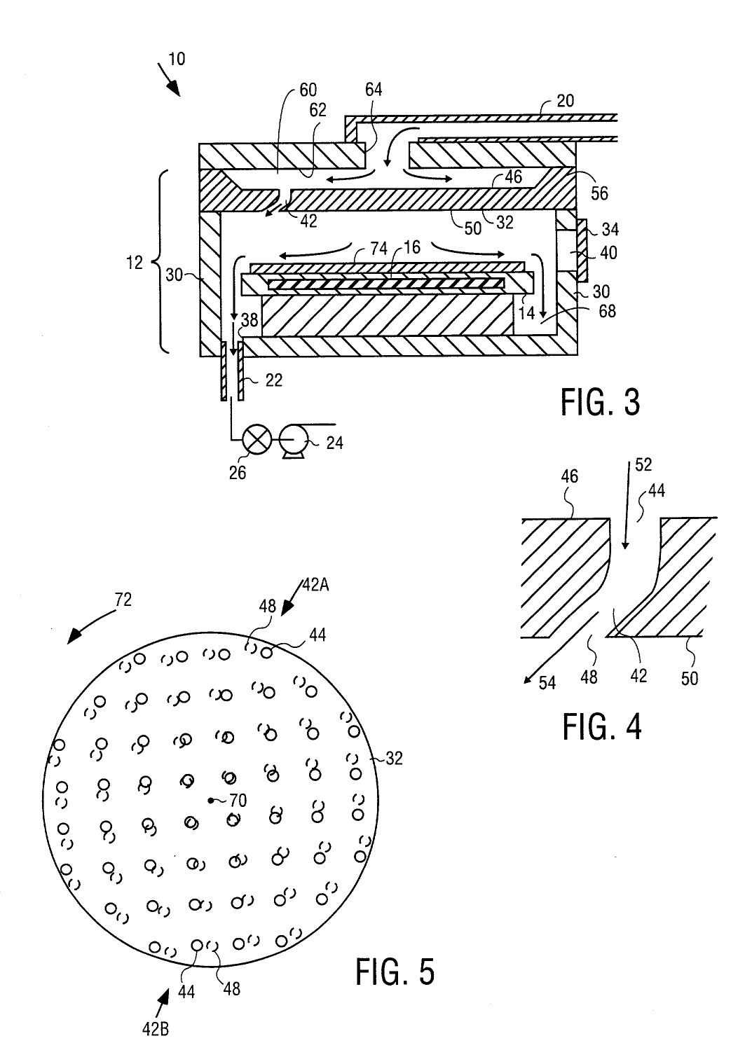

FIG. 3 of the accompanying drawings illustrates wafer processing apparatus 10 according to an embodiment of the invention. The apparatus 10 includes a wafer processing chamber 12, a susceptor 14, a resistive heating element 16, a manifold component 18, a gas supply line 20, an exhaust line 22, a pump 24, and a control valve 26.

The chamber 12 has a lower wall 28, sidewalls 30, an upper wall 32, and a slitvalve 34. The lower wall 28 forms a base of the chamber 12. An opening 38 is formed in the lower wall 28 on a side thereof. The side walls 30 extend upwardly from edges of the lower wall 28. A wafer supply opening 40 is formed in one of the sidewalls 30. The supply opening 40 has dimensions which allow for a wafer to be inserted into the chamber 12 in a horizontal orientation. The slitvalve 34 is mounted to the chamber 12 for movement between a position wherein the slitvalve 34 closes the wafer supply opening 40 and a position wherein the slitvalve 34 is moved out of the way of the wafer supply opening 40 to allow for insertion of a wafer into the chamber 12. The upper wall 32 is located on upper edges of the sidewalls 30. A plurality of gas supply openings 42 are formed through the upper wall 32.

FIG. 4 illustrates one of the openings 42 in more detail. The opening 42 has an upper end 44 formed into an upper surface 46 of the upper wall 32. The opening 42 extends vertically downwardly into the upper wall 46, whereafter the opening 42 changes direction. A lower end 48 of the opening 42 extends out of a lower surface 50 of the upper wall 32. The lower end 48 extends at an angle of, for example, about 45° relative to vertical. A gas can flow into the upper end 44 in a vertical direction 52 and exit from the lower end 48 in a direction 54 at an angle of, in the present example, about 45° relative to vertical.

Referring again to FIG. 3, the upper wall 32 is formed with a peripheral edge 56. The peripheral edge 56 extends upwardly from an edge of the upper surface 46. The manifold component 18 is located on the peripheral edge 56. A manifold cavity 60 is defined between the upper surface 46, a lower surface 62 of the manifold component 18, and inner surfaces of the peripheral edge 56. A gas supply opening 64 is formed centrally in the manifold component 18.

The gas supply line 20 is connected to the manifold component 18. A gas can flow through the gas supply line 20 into the manifold cavity 60. The exhaust line 22 is connected to the opening 38 so that a gas can flow from the chamber 12 into the exhaust line 22. The exhaust line 22 is connected to a pump 24 through a control valve 26.

The susceptor 14 is located centrally on an upper surface of a lower wall 28. A channel 68 is formed concentrically around the susceptor 14. The resistive heating element 16 is located within an upper portion of the susceptor 14. The resistive heating element 16 is connected to a power supply (not shown). The power supply can be operated to supply current to the resistive heating element 16 to cause the resistive heating element 16 to heat up.

FIG. 5 illustrates the upper wall 32 in more detail. The upper wall 32 is shown as viewed from above. The upper wall 32 has a center point 70. The openings 42 are located around the center point 70. Upper ends 44 of the openings are shown in solid lines and lower ends 48 of the openings are shown in hidden lines. The lower end 48 of a particular opening is displaced in an angular direction 72 relative to an upper end 44 thereof. As such one opening 42A on one side of the center point 70 has a lower end 48 which is displaced in the angular direction 72 relative to the upper end 44 thereof and another opening 42B, located on a side of the center point 70 opposing the opening 42A, also has a lower end 48 which is displaced relative to the upper end 44 thereof in the angular direction 72 about the center point 70.

In use, the slitvalve 34 is moved into its open position. A wafer 74 is then transferred, on a blade that is moved by a robot, through the wafer supply opening 40 into the chamber 12. The wafer 74 is located on an upper surface of the susceptor 14. The blade carrying the wafer 74 into the chamber 12 is then removed through the wafer supply opening 40 and the slitvalve 34 is closed.

A current is then provided through the resistive heater elements 16, thereby heating the resistive heating elements 16. The resistive heating element heats the susceptor 14, which, in turn, heats the wafer 74. The wafer 74 is heated to a required processing temperature.

The pump 24 is operated and the control valve 26 opened. A vacuum is thereby created within the chamber 12. Because of the vacuum in the chamber 12, a gas is drawn through the gas supply line 20 into the manifold cavity 60. The gas then flows through the openings 42 into the chamber 12.

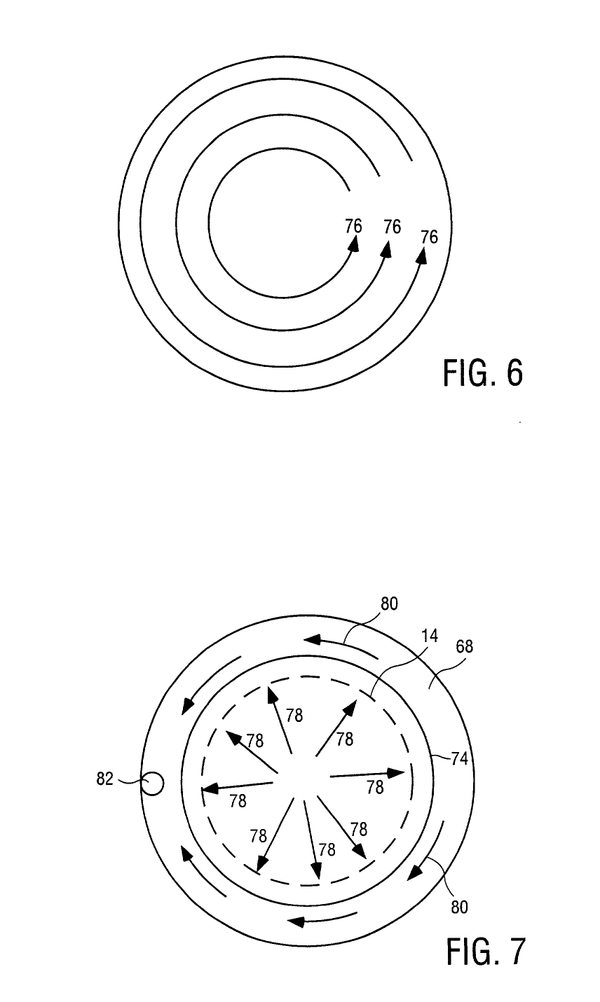

FIG. 6 illustrates a flow pattern of the gas upon exit from lower ends of the openings 32. Because of the angle at which the gas exits in the direction 54 shown in FIG. 4, and the relative positionings of the lower ends 48 relative to the upper ends 44 of the openings as shown in FIG. 5, circular flow is imparted on the gas. The gas initially moves in a direction 76. The direction 76 is the same direction as the direction 72 shown in FIG. 5. The circular movement in the direction 76 counteracts a tendency of the gas to flow directly towards the exhaust line 22. More even processing over an upper surface of the wafer 74 is thereby promoted. The gas flowing through the chamber 12 and over the wafer also has a radial component 78 as shown in FIG. 7. The gas flows from the central region of the wafer 74 radially outwardly towards a peripheral edge of the wafer 74 and then over the peripheral edge of the wafer 74 downwardly into the channel 68.

Gas accumulates in the channel 68 and then flows around the susceptor in directions 80 towards a location 82 where the exhaust line 22 is connected. The flow shown in FIGS. 6 and 7 is entirely laminar at all times.

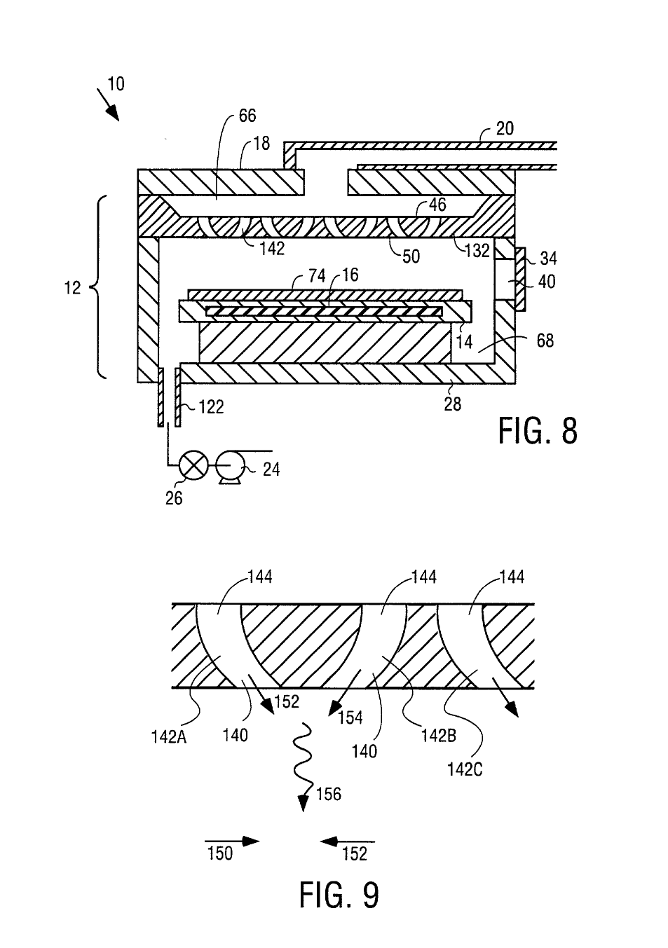

FIG. 8 illustrates the apparatus 10 having an upper wall 132, according to another embodiment of the invention. The upper wall 132 has a plurality of openings 142 formed therein.

As shown in FIG. 9, each opening 142 has an upper end 144 and a lower end 146. A lower end 140 of a first opening 142 is displaced in a direction 148 relative to an upper end 144 thereof. The lower end 140 of a second opening 142 is displaced in a direction 150, opposing the direction 152, relative to an upper end 134 thereof. The opening 142B is located adjacent the opening 142A. An opening 142C is located on a side of the opening 142B opposing the opening 142A. The opening 142C has a lower end 140 which is displaced in the direction 150 relative to the upper end 144 thereof. Gases flow in directions 152 and 154 downwardly and towards one another out of lower ends 130 of the openings 142A and 142B respectively. Collision of the gases causes turbulent flow 156 in a substantially downward direction. In a similar manner gases from the opening 142C and another opening (not shown) adjacent the opening 142C collide to cause turbulent flow. The turbulent flow 156 counteracts a tendency of the gas to flow directly to an exhaust line 122. Other aspects of the apparatus 10 shown in FIG. 8 are the same as the apparatus 10 of FIG. 3.

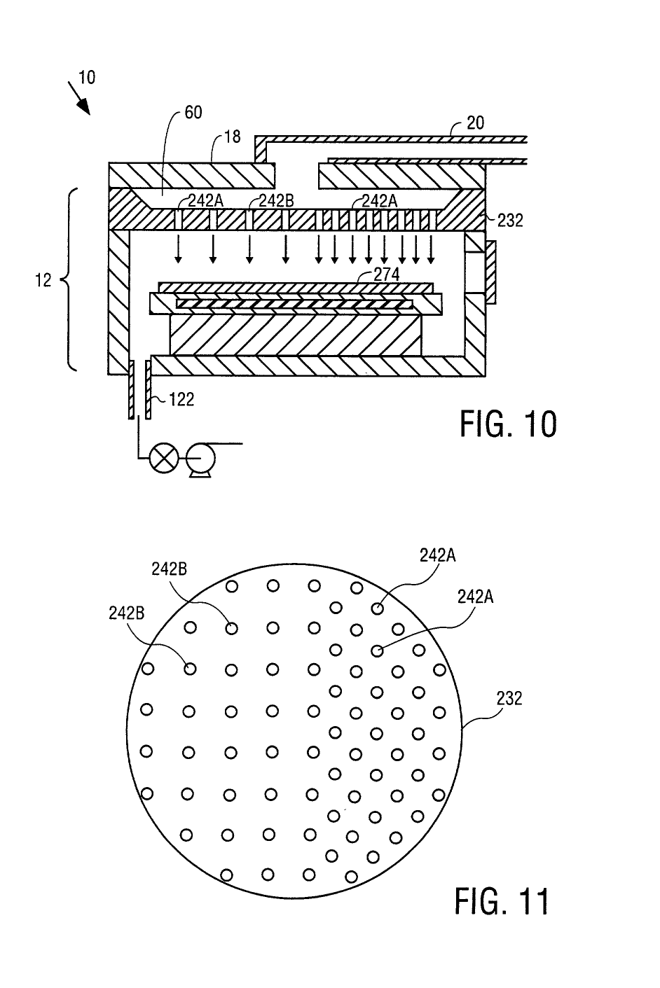

FIG. 10 illustrates apparatus 10 having an upper wall 232 according to a further embodiment of the invention. A plurality of entirely vertical and straight openings 242 are formed through the upper wall 232. The openings 242 in a right-hand half of the upper wall 232 are more densely populated than the openings 242B in a left hand half of the other wall 232. There are about twice as many ones of the openings 242A in a given area of the right-hand half of the upper wall 232 than the openings 242B over an equivalent area of the left hand half of the upper wall 232. All the openings 242A and 242B have the same diameter.

Because of more openings in the right-hand half of the upper wall 232, more of the gas is supplied into a right-hand half of the chamber. The flowrate of the gas over a right-hand half of the wafer 274 is thereby increased. Should there be an equal number of vertical openings, the flowrate over the left hand half of the wafer 274 would be greater than the flowrate over the right-hand half of the wafer 274 because of the tendency of the flow to be towards the left over the wafer 274. The increase in the number of openings in the right-hand half of the upper wall 232 thus counteracts the tendency for the flow to be higher over the left of the wafer 274.

FIG. 11 is a plan view illustrating the upper wall 232. It can be seen that the openings 242A are located over the entire right-hand half of the upper wall 242 and the openings 242B are located over the entire left hand half of the upper wall 232.

While certain exemplary embodiments have been described and shown in the accompanying drawings, it is to be understood that such embodiments are merely illustrative and not restrictive of the current invention, and that this invention is not restricted to the specific constructions and arrangements shown and described since modifications may occur to those ordinarily skilled in the art.

What is claimed:

1. A wafer processing apparatus comprising:
a processing chamber defined by a lower wall, an upper wall and side walls extending from the lower wall to the upper wall, a wafer supply opening being formed in one of the walls for transferring a wafer into the chamber, and the upper wall having a plurality of gas supply openings, each formed into an upper surface and out of a lower surface thereof;
a susceptor in the chamber on which the wafer can be located so that an upper surface of the wafer faces the upper wall;
a manifold component located on the chamber and, together with the upper surface of the upper wall, defining a manifold cavity;
a gas supply line connected to the manifold component, a gas, when flowing in the gas supply line, flowing from the gas supply line into the manifold cavity and from the manifold cavity through the gas supply openings into the chamber so that the wafer is exposed to the gas, lower ends of at least some of the openings extending at an angle other than at right angles relative to the upper surface of the wafer so that the gas, when exiting the openings flows at an angle other than at right angles relative to the upper surface, a flow pattern created by flow from the openings promoting even processing over the upper surface of the wafer; and
an exhaust line connected to the gas chamber, the gas flowing from the chamber through the exhaust line.

2. The apparatus of claim 1 wherein, when viewed from above, at least some of the openings each have a lower end which is displaced relative to an upper end thereof.

3. The apparatus of claim 2 wherein there are first and second ones of the openings on opposing sides of a point on the upper wall, the first opening having a lower end which is angularly displaced relative to an upper end thereof in a selected direction about the point, and the second opening having a lower end which is angularly displaced relative to an upper end thereof in the selected direction, so that the openings jointly created a circular flow pattern in the chamber.

4. The apparatus of claim 3 wherein flow of the gas in the chamber is laminar.

5. The apparatus of claim 2 wherein there are first and second ones of the openings, the first opening having a lower end which is displaced in a first direction relative to an upper end thereof, and the second opening having a lower end which is displaced in a second, opposing direction relative to an upper end thereof.

6. The apparatus of claim 5 wherein flow of the gas in the chamber is turbulent.

7. The apparatus of claim 5 wherein a third of the openings, on a side of the second opening opposing the first opening, has a lower end which is displaced in the first direction relative to an upper end thereof.

8. The apparatus of claim 7 wherein the flow is turbulent.

9. The apparatus of claim 1 wherein the exhaust line is connected at an exhaust location which is off-center with respect to a center point of the wafer, when viewed from above, so that the gas exits out of the wafer at the exhaust location which is off-center with respect to a center point of the wafer.

10. The apparatus of claim 9 wherein a channel is defined within the chamber, the channel being concentric with the wafer, gas flowing radially outwardly over the wafer into the channel, and from the channel to the exhaust location and into the exhaust line.

11. The apparatus of claim 10 wherein the openings are formed to increase a flowrate of the gas over the wafer farther from the exhaust location.

12. A wafer processing apparatus, comprising:
a processing chamber defined by a lower wall, an upper wall and side walls extending from the lower wall to the upper wall, a wafer supply opening being formed in one of the walls for transferring a wafer into the chamber, and the upper surface and out of a lower surface thereof;
a susceptor in the chamber on which the wafer can be located so that an upper surface of the wafer faces the upper wall;
a manifold component located on the chamber and, together with the upper surface of the upper wall, defining a manifold cavity;
a gas supply line connected to the manifold component, a gas, when flowing in the gas supply line, flowing from the gas supply line into the manifold cavity and from the manifold cavity through the gas supply openings into the chamber so that the wafer is exposed to the gas, the gas supply openings being nonuniformly distributed over the upper wall so that the gas, after leaving the gas supply openings, creates a flow pattern that promotes even processing over the upper surface of the wafer; and
an exhaust line connected to the gas chamber, the gas flowing from the chamber through the exhaust line.

13. The apparatus of claim 12 wherein the openings are more densely located on one side of the upper wall than on another side thereof.

14. The apparatus of claim 13 wherein the openings are substantially equal in size.

15. The apparatus of claim 12 wherein flow of gas in the chamber is laminar.

16. The apparatus of claim 12 wherein the exhaust line is connected at an exhaust location which is off-center with respect to a center point of the wafer, when viewed from above, so that the gas exits out of the chamber at the exhaust location which is off-center with respect to a center point of the wafer.

17. The apparatus of claim 16 wherein a channel is defined within the chamber, the channel being concentric with the wafer, gas flowing radially outwardly over the wafer into the channel, from the channel, to the exhaust location into the exhaust line.

18. The apparatus of claim 17 wherein the openings are more densely located farther from the exhaust location.

19. A wafer processing apparatus, comprising:
a processing chamber defined by a lower wall, an upper wall and side walls extending from the lower wall to the upper wall, a wafer supply opening being formed in one of the walls for transferring a wafer into the chamber, and the upper wall having a plurality of gas supply openings, each formed into an upper surface and out of a lower surface thereof;
a susceptor in the chamber on which the wafer can be located so that an upper surface of the wafer faces the upper wall;
a manifold component located on the chamber and, together with the upper surface of the upper wall, defining a manifold cavity;
a gas supply line connected to the manifold component; and
an exhaust line connected to the chamber, a gas, when flowing in the gas supply line, flowing from the gas supply line into the manifold cavity and from the manifold cavity through the gas supply openings into the chamber so that the wafer is exposed to the gas, the gas flowing from the chamber through the exhaust line, the exhaust line being connected to the chamber at an exhaust location off-center with respect to a center point of the wafer so that flow over the wafer closest to the exhaust location tends to be faster than over an area of the wafer farther from the exhaust location if the gas supply openings are uniformly spaced and entirely vertical, the gas supply openings being formed so as to reduce the tendency for the flow to be faster over the wafer closest to the exhaust location than at the location farther form the exhaust location so as to promote even processing of the wafer.

20. The apparatus of claim 19 wherein a channel is defined within the chamber, the channel being concentric with the wafer, gas flowing radially outwardly over the wafer into the channel, from the channel, to the exhaust location into the exhaust line.
